(19) United States
(12) Patent Application Publication
(10) Pub. No.: US 2026/0323857 A1
(43) Pub. Date: Oct. 15, 2026

(54) HANDLE APPARATUS FOR INSTALLING COMPONENTS IN COMPUTING SYSTEMS

(71) Applicant: Quanta Computer Inc., Taoyuan City (TW)

(72) Inventors: Yaw-Tzorng TSORNG, Taoyuan City (TW); Jen-Jia LIOU, Taoyuan City (TW); Wei-Jie CHEN, Taoyuan City (TW); Yu-Tung YANG, Taoyuan City (TW)

(21) Appl. No.: 19/262,527

(22) Filed: Jul. 8, 2025

Related U.S. Application Data
(60) Provisional application No. 63/789,012, filed on Apr. 15, 2025.

(51) Int. Cl. H05K 7/14

(52) U.S. Cl. CPC H05K 7/1401; H05K 7/1489

(57) ABSTRACT

A handle apparatus for receiving an interconnect bridge of a computing system is disclosed. The handle apparatus includes a grip attachment and a bracket, coupled to the grip attachment. The bracket includes a first and second bracket portion, an inner fin, and an outer fin. The first bracket portion has a first top surface and a first bottom surface. The first top surface is located opposite the first bottom surface. The second bracket portion has a second top surface and a second bottom surface. The second top surface is located opposite the second bottom surface. The first top surface is coupled with the second top surface via the grip attachment. The outer fin is separated from the inner fin by a fin spacing. The outer fin is parallel to the inner fin. The outer fin and the inner fin couple the first and second bottom surfaces.

### CROSS-REFERENCE TO RELATED APPLICATIONS

This application claims priority from and benefit of U.S. Provisional Patent Application Ser. No. 63/789,012, filed on Apr. 15, 2025, titled “NV LINK BRIDGE HANDLE,” which is hereby incorporated by reference herein in its entirety.

### FIELD OF THE INVENTION

The present invention relates generally to system and methods for installing components in computing systems, and more specifically, a handle apparatus that facilitates installing and/or removing mostly planar components in computing systems.

### BACKGROUND OF THE INVENTION

Computing systems typically have electronic components housed in a chassis. Examples of computing systems include desktop computers, blade servers, rack-mount servers, etc. Servers are employed in a large number of applications ranging from high-performance computing to database storage. Servers enable many computing application solutions that have come to be relied upon. For example, servers may support mobile application solutions such as mobile mapping applications, mobile payment systems, text messaging, computation offloading, web browsing, etc. Mobile customers are usually unaware of extensive support being provided by servers in everyday use of their mobile devices. Although mobile customers may not consider server-side support in everyday use of mobile devices, components that make up the server affect the performance of the server, and in some cases, the features available for computing. Thus, servers sometimes need to be configured to include specific components or need to be upgradable to include specific components.

When upgrading hardware components, sometimes older components are taken out and replaced with newer components. Sometimes a new interconnect (e.g., a jumper) is introduced, providing a new avenue for hardware components to communicate with each other. For example, graphical processing units (GPUs) installed in peripheral component interconnect express (PCIe) slots can communicate with each other through the PCIe interface of a motherboard of the server. During an upgrade, an NVLink bridge can be added such that the GPUs communicate directly with each other, in addition to (or instead of) communicating with each other using the PCIe interface. The NVLink bridge can provide faster connectivity and communication between the GPUs compared to the PCIe interface.

After installing the NVLink bridge, the NVLink bridge adheres closely to the surface of the GPU cards, making removal of the NVLink bridge difficult. Furthermore, NVLink bridges do not have guiding structures for installation. Prying the NVLink bridge out of the connectors of the GPU cards during removal or attempting to install the NVLink bridge in an incorrect orientation can result in damage to connectors on the NVLink bridge. The present disclosure provides solutions that at least reduce the difficulty associated with installing and/or removing interconnect bridges in computing systems.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a handle apparatus for receiving an interconnect bridge of a computing system is provided. The handle apparatus includes a grip attachment and a bracket, coupled to the grip attachment. The bracket includes a first and second bracket portion, an inner fin, and an outer fin. The first bracket portion has a first top surface and a first bottom surface. The first top surface is located opposite the first bottom surface. The second bracket portion has a second top surface and a second bottom surface. The second top surface is located opposite the second bottom surface. The first top surface is coupled with the second top surface via the grip attachment. The outer fin is separated from the inner fin by a fin spacing. The outer fin is parallel to the inner fin. The outer fin and the inner fin couple the first and second bottom surfaces.

In an implementation, the grip attachment includes a first grip portion and a second grip portion. Each of the first grip portion and the second grip portion independently couple the first bracket portion to the second bracket portion on the top surfaces associated with the first bracket portion and the second bracket portion. In an implementation, the inner fin includes a first inner fin, a second inner fin, and a third inner fin. The first grip portion is positioned in a spacing between the outer fin and the first inner fin, and the second grip portion is positioned in a spacing between the second inner fin and the third inner fin. In an implementation, the grip attachment includes a first grip having a grip body made with elastic material.

In an implementation, the outer fin includes one or more stoppers configured to prevent motion of the interconnect bridge in a single lateral direction. In an implementation, the first bracket portion includes a first stopper or the second bracket portion includes a second stopper. The first stopper and/or the second stopper prevents motion of the interconnect bridge in a single lateral direction. In an implementation, the interconnect bridge is: (i) prevented from moving in a first direction by the inner fin; (ii) prevented from moving in a second direction by the outer fin; (iii) prevented from moving in a third direction by the grip attachment; (iv) prevented from moving in a fourth direction and a fifth direction by the first bracket portion; and (v) prevented from moving in the fourth direction and a sixth direction by the second bracket portion. The first direction, the second direction, the third direction, the fourth direction, the fifth direction, and the sixth direction are all different directions. In an implementation, the interconnect bridge is an NVLink bridge.

According to certain aspects of the present disclosure, a computing system is provided. The computing system includes a circuit board, a plurality of computing expansion cards electrically coupled to the circuit board, and a first bridge-handle combination. The plurality of computing expansion cards includes a first set of computing expansion cards. The first bridge-handle combination is coupled to the first set of computing expansion cards. A bridge-handle combination includes a handle apparatus securing an interconnect bridge. The handle apparatus includes a grip attachment and a bracket, coupled to the grip attachment. The bracket includes a first and second bracket portion, an inner fin, and an outer fin. The first bracket portion has a first top surface and a first bottom surface. The first top surface is located opposite the first bottom surface. The second bracket portion has a second top surface and a second bottom surface. The second top surface is located opposite the second bottom surface. The first top surface is coupled with the second top surface via the grip attachment. The outer fin is separated from the inner fin by a fin spacing. The outer fin is parallel to the inner fin. The outer fin and the inner fin couple the first and second bottom surfaces.

In an implementation, the circuit board is a motherboard and the plurality of computing expansion cards is a plurality of graphical processing units. In an implementation, the interconnect bridge of the first bridge-handle combination is an NVLink bridge. In an implementation, the computing system further includes a second bridge-handle combination, and the plurality of computing expansion cards further includes a second set of computing expansion cards. The second set of computing expansion cards is coupled to the second bridge-handle combination. In an implementation, the grip attachment includes a first grip portion and a second grip portion. Each of the first grip portion and the second grip portion independently couple the first bracket portion to the second bracket portion on the top surfaces associated with the first bracket portion and the second bracket portion.

In an implementation, the inner fin includes a first inner fin, a second inner fin, and a third inner fin. The first grip portion is positioned in a spacing between the outer fin and the first inner fin, and the second grip portion is positioned in a spacing between the second inner fin and the third inner fin. In an implementation, the grip attachment includes a first grip having a grip body made with elastic material. In an implementation, the outer fin includes one or more stoppers. The one or more stoppers are configured to prevent motion of the interconnect bridge in a single lateral direction. In an implementation, the first bracket portion includes a first stopper, or the second bracket portion includes a second stopper. The first stopper and/or the second stopper is configured to prevent motion of the interconnect bridge in a single lateral direction. In an implementation, a separation between connectors of the interconnect bridge is the fin spacing. In an implementation, the first bracket portion includes an orientation marker. In an implementation, the orientation marker points toward a PCI bracket of the computing expansion cards.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a perspective view showing an interconnect bridge and a set of computing expansion cards in the prior art.

FIG. 2 is a perspective view showing connector matings of the interconnect bridge and the set of computing expansion cards of FIG. 1.

FIG. 3 is a picture of a damaged connector on an NVLink bridge.

FIG. 4 is a perspective view showing an interconnect bridge being inserted in a handle apparatus, according to certain aspects of the present disclosure.

FIG. 4A is a perspective view showing a handle apparatus with a pivotable grip attachment, according to certain aspects of the present disclosure.

FIG. 4B is a perspective view showing the handle apparatus of FIG. 4 with a flexible grip attachment, according to certain aspects of the present disclosure.

FIG. 5 is a top perspective view showing a bridge-handle combination, according to certain aspects of the present disclosure.

FIG. 6 is a bottom perspective view of the bridge-handle combination of FIG. 5.

FIG. 7 is a bottom perspective view of an incorrectly installed bridge-handle combination.

FIG. 8 is a perspective view showing the bridge-handle combination of FIG. 5 and a set of expansion cards.

FIG. 9 is a cross-sectional view of the bridge-handle combination and the set of expansion cards of FIG. 8.

FIG. 10 is a perspective view showing connector matings of the bridge-handle combination and the set of computing expansion cards of FIG. 8.

FIG. 11 is a cross-sectional view of the incorrectly installed bridge-handle combination of FIG. 7 aligned with a set of expansion cards, according to certain aspects of the present disclosure.

FIG. 12 is a perspective view showing connector positioning of FIG. 11, according to certain aspects of the present disclosure.

FIG. 13 is a perspective view showing bridge-handle combinations being installed in a computing system, according to certain aspects of the present disclosure.

FIG. 14 is a perspective view of the computing system of FIG. 13 after installing the bridge-handle combinations, according to certain aspects of the present disclosure.

FIG. 15 is a perspective view of the bridge-handle combinations of FIG. 14 highlighting orientation markers of the bridge-handle combinations.

FIG. 16 is a top plan view of one of the bridge-handle combinations of FIG. 14 highlighting positions of stoppers, according to certain aspects of the present disclosure.

FIG. 17 is a perspective view showing removal of one of the bridge-handle combinations of FIG. 14.

### DETAILED DESCRIPTION

After installing an NVLink bridge, the NVLink bridge adheres closely to the surface of the GPU card, making the removal process difficult. As a result, users often need to pry the NVLink bridge up from both sides using their fingers or a sharp object. Prying the NVLink bridge in this manner can damage connectors of the NVLink bridge. For example, contact springs of the connectors can become damaged. Additionally, when prying up the NVLink bridge, users typically lift one side first before the other, causing the NVLink bridge to tilt unevenly, further increasing the risk of connector damage. Moreover, the NVLink bridge lacks guiding structures, making the NVLink bridge prone to installation errors, such as being inserted backward or at an angle, which may lead to connector damage. Embodiments of the present disclosure provide a handle apparatus that couples to an interconnect bridge (e.g., an NVLink bridge). The handle apparatus is a fail-safe mechanism to effectively prevent installation and removal errors associated with interconnect bridges, enhancing user experience without requiring additional tools while also reducing the risk of damage. The handle apparatus provides an orientation marker and secures the interconnect bridge, thus allowing easy installation and removal of the interconnect bridge.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

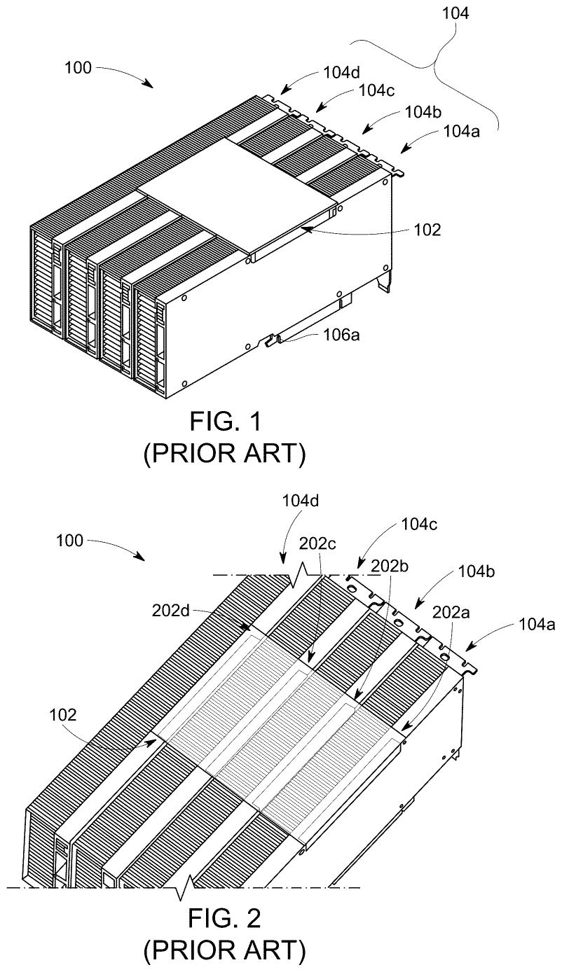

Referring to FIG. 1, a perspective view showing a set of connected cards 100 in the prior art is provided. The set of connected cards 100 includes an interconnect bridge 102 and a set of computing expansion cards 104. The set of computing expansion cards 104 includes a first computing expansion card 104a, a second computing expansion card 104b, a third computing expansion card 104c, and a fourth computing expansion card 104d. The first computing expansion card 104a includes a board connector 106a.

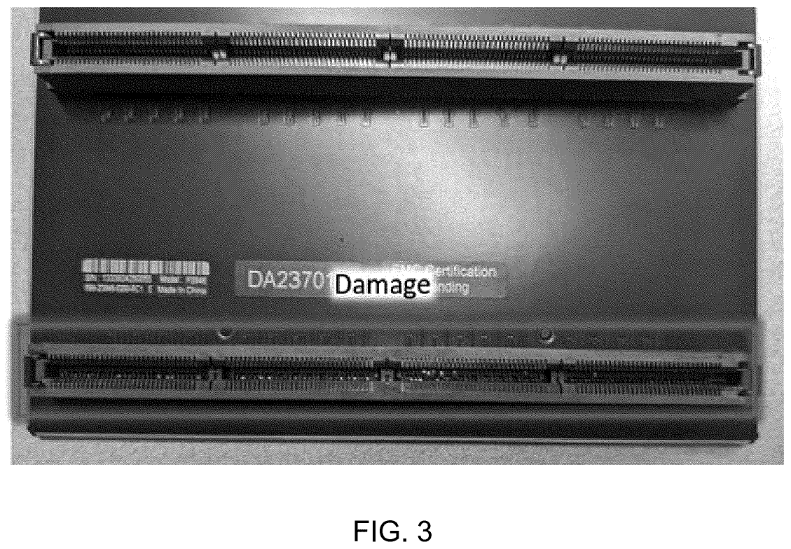

Referring to FIG. 2, a perspective view showing connector matings 202a, 202b, 202c, 202d of the interconnect bridge 102 and the set of computing expansion cards 104 of FIG. 1. The connector matings 202a, 202b, 202c, 202d show coupling between connectors of the interconnect bridge 102 and connectors of the set of computing expansion cards 104. Thickness of the interconnect bridge 102 can be, for example, about 60 mm including height of connectors of the interconnect bridge 102.

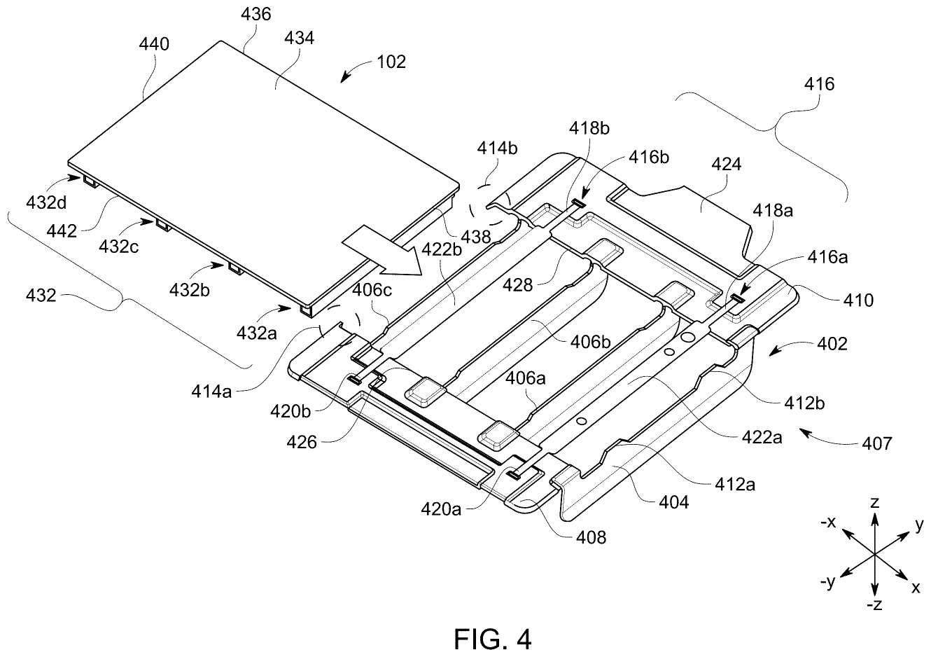

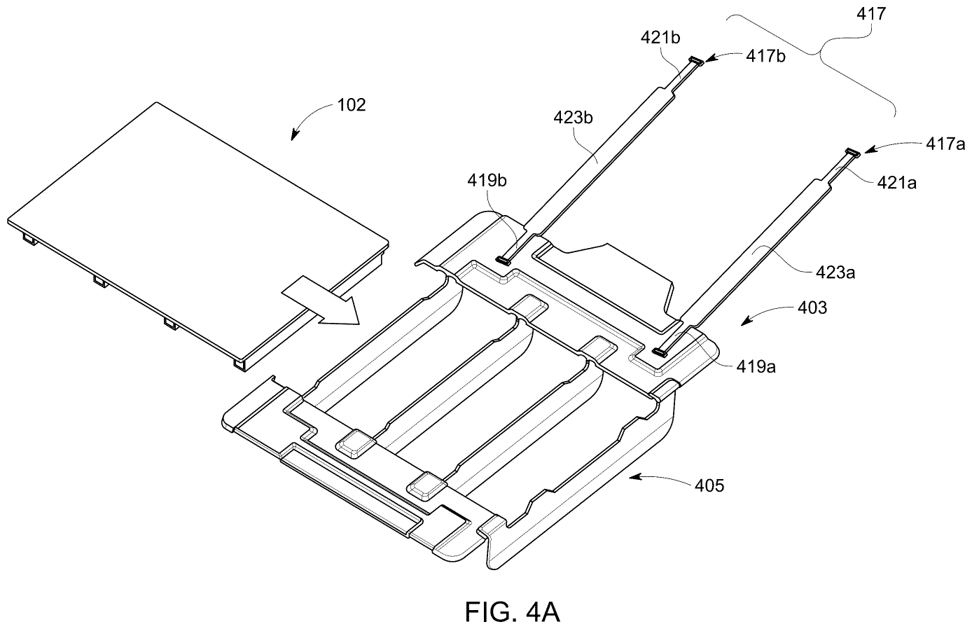

Structural and electrical integrity of the interconnect bridge 102 can be compromised from installing the interconnect bridge 102 in an incorrect orientation or at an angle. Furthermore, prying the interconnect bridge 102 to remove from the set of computing expansion cards 104 can also compromise structural and electrical integrity of the interconnect bridge 102. For example, FIG. 3 is a picture of a damaged connector on an NVLink bridge. Connectors on the NVLink bridge are directional and should be installed in a proper and correct orientation. Forcing the NVLink bridge in an incorrect manner can damage at least one of the connectors as shown in FIG. 3. Therefore, embodiments of the present disclosure provide a handle apparatus for reducing installation and removal errors as provided in FIG. 4.

FIG. 4 is a perspective view showing the interconnect bridge 102 being inserted in a handle apparatus 402, according to certain aspects of the present disclosure. The interconnect bridge 102 includes two or more connectors 432—for example, a first connector 432a, a second connector 432b, a third connector 432c, a fourth connector 432d. The interconnect bridge 102 has a top surface 434 and multiple side edges including a first side edge 436, a second side edge 442, a third side edge 438, and a fourth side edge 440. In some implementations, dimensions of the interconnect bridge 102 are about 215 mm for the length of the third and fourth side edges 438, 440 and about 250 mm for the length of the first and second side edges 436, 442. Thickness of the side edges can be about 2.20 mm. In some implementations, dimensions of the interconnect bridge 102 are about 104.9 mm for the length of the third and fourth side edges 438, 440 and about 129.89 mm for the length of the first and second side edges 436, 442. Thickness of the side edges can be about 2.20 mm.

In some implementations, an interconnect bridge can have the following dimensions: 50.3 mm to 104.9 mm for the length of the third and fourth side edges, 40.64 mm to 129.89 mm for the length of the first and second side edges, and 2.20 mm to 2.22 mm for thickness of the side edges. The connectors of the interconnect bridge (e.g., connectors 432a-d) can have a thickness of about 9.33 mm, such that when added to the thickness of the side edges, the interconnect bridge can have a total thickness (including the connectors) of about 11.40 mm to 11.55 mm. As described above, interconnect bridges can have only two connectors (e.g., connectors 432a-b), and the lower bound of the quoted dimensions correspond to the two-connector versions of interconnect bridges while the upper bound of the quoted dimensions correspond to four-connector versions of interconnect bridges. For example, 50.3 mm length corresponds to a two-connector interconnect bridge, and 104.9 mm length corresponds to a four-connector interconnect bridge (e.g., the interconnect bridge 102).

The handle apparatus 402 includes a bracket 407 and a grip attachment 416. The bracket 407 is coupled to the grip attachment 416. The grip attachment 416 includes one or more grip portions, for example, a first grip portion 416a and a second grip portion 416b. In some implementations, for an interconnect bridge having only two connectors, the grip attachment 416 can have only one grip portion, for example, only the first grip portion 416a. In some implementations, for an interconnect bridge having only two connectors, the grip attachment 416 can have two grip portions with a separation between the two grip portions being less than the separation between the first grip portion 416a and the second grip portion 416b of FIG. 4.

The bracket 407 includes a first bracket portion 410, a second bracket portion 408, an outer fin 404 and one or more inner fins (e.g., a first inner fin 406a, a second inner fin 406b, and a third inner fin 406c). The outer fin 404 and/or the one or more inner fins (e.g., the first inner fin 406a) couple the first bracket portion 410 to the second bracket portion 408. The outer fin 404 is arranged parallel to at least one of the inner fins (e.g., the first inner fin 406a).

In some implementations, outermost fins (e.g., the outer fin 404 and the third inner fin 406c) are coupled to both the first bracket portion 410 and the second bracket portion 408, and non-outermost fins (e.g., the first inner fin 406a and second inner fin 406b) are coupled to only one of the first bracket portion 410 or the second bracket portion 408. For example, the first inner fin 406a can be directly coupled to the first bracket portion 410 and not directly coupled to the second bracket 408, and the second inner fin 406b can be directly coupled to the second bracket portion 408 and not directly coupled to the first bracket portion 410.

In some implementations, only the outermost fins (e.g., the outer fin 404 and the third inner fin 406c) are provided, and the non-outermost fins (e.g., the first inner fin 406a and the second inner fin 406b) are not provided. Providing the outermost fins allows the outermost fins to lift the interconnect bridge 102 closer to the side edges (e.g., the third side edge 438 and the fourth side edge 440) when removing the interconnect bridge 102. In some implementations, the number of fins (e.g., the outer fin 404, the first inner fin 406a, the second inner fin 406a, and the third inner fin 406c) match the number of connectors 432 (e.g., the first connector 432a, the second connector 432b, the third connector 432c, the fourth connector 432d). Matching the number of fins to the number of connectors 432 allows each of the fins to lift the interconnect bridge 102 at locations on the interconnect bridge 102 proximate to each of the connectors 432. Fins provided at locations that are proximate to locations of each of the connectors 432 reduce warping of the connectors 432 when removing the interconnect bridge 102.

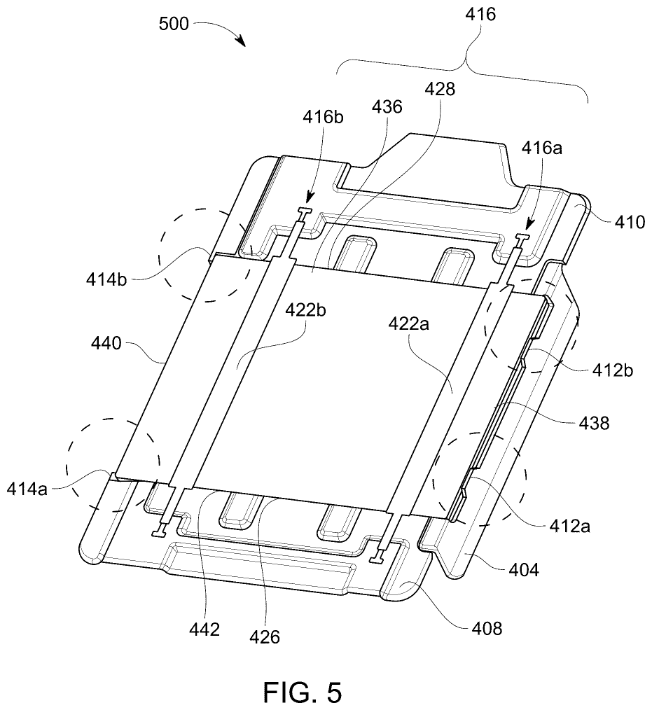

In some implementations, the outer fin 404 and/or the one or more inner fins couple the first bracket portion 410 to the second bracket portion 408 on bottom surfaces associated with the first bracket portion 410 and the second bracket portion 408. In some implementations, the grip attachment 416 couples the first bracket portion 410 to the second bracket portion 408 on top surfaces associated with the first bracket portion 410 and the second bracket portion 408. The bottom surfaces associated with the first bracket portion 410 and the second bracket portion 408 are located opposite the top surfaces associated with the first bracket portion 410 and the second bracket portion 408. In some implementations, when multiple grip portions (e.g., the first grip portion 416a and the second grip portion 416b) are provided, each of the grip portions independently couples the first bracket portion 410 to the second bracket portion 408. In the perspective view of FIG. 4, the top surfaces associated with the first bracket portion 410 and the second bracket portion 408 are visible. The perspective view of FIG. 6 reveals bottom surfaces associated with the first bracket portion 410 and the second bracket portion 408.

In some implementations, grip portions can include grip ends. For example, the first grip portion 416a can have a first grip end 418a and a second grip end 420a, and the second grip portion 416b can have a first grip end 418b and a second grip end 420b. The grip ends (e.g., the first grip ends 418a, 418b and second grip ends 420a, 420b) directly couple to the bracket portions (e.g., the first bracket portion 410 and the second bracket portion 408). In some implementations, the coupling to the bracket portions 410, 408 is a removable coupling. For example, using a removable fastener, screws, nuts and bolts, bolts and latches, etc. In some implementations, the coupling to the bracket portions 410, 108 facilitates pivoting of the grip portions 416a, 416b at either the first grip ends 418a, 418b or the second grip ends 420a, 420b. Removable coupling and pivoting coupling can allow for removing the grip attachment 416 to create space for the interconnect bridge 102 to be received at a spacing between the grip attachment 416 and the outer fin 404 and the inner fins 406a, 406b, 406c.

FIG. 4A provides an example handle apparatus 403 where a grip attachment 417 can be removed and pivoted to create space for the interconnect bridge 102. The grip attachment 417 includes a first grip portion 417a and a second grip portion 417b coupled to a bracket 405. The bracket 405 is similar to the bracket 407 (FIG. 4) but includes: (i) couplers that allow pivoting first grip ends (e.g., first grip ends 419a, 419b) about the bracket 405; and (ii) couplers that allow detaching second grip ends (e.g., second grip ends 421a, 421b) from the bracket 405. FIG. 4A is merely provided as an example, but in some implementations, all couplers are removable such that the grip attachment 417 can be fully detached from the bracket 405. In some implementations, the first and second grip portions 417a, 417b are coupled with a member (not shown) that allows both the first and second grip portions 417a, 417b to pivot together as a single unit. The member can be a connecting bar that: (i) attaches to both the second grip end 421a and the second grip end 421b; or (ii) attaches to both a first grip body 423a and a second grip body 423b.

Referring to FIG. 4, in some implementations, grip portions include grip bodies (e.g., a first grip body 422a and a second grip body 422b). A grip body is a location along a grip portion that a user or a service person can hold on to when installing or removing an interconnect bridge from a computing system. For example, a user can grab onto and pull both the first grip body 422a and the second grip body 422b. The first grip body 422a and the second grip body 422b simplify handling of the interconnect bridge 102. In some implementations, grip bodies are made with elastic material such that the first grip body 422a and the second grip body 422b expand to accommodate a user's hand or expand to create space for the interconnect bridge 102 to be received at a spacing between the grip attachment 416 and the outer fin 404 and the inner fins 406a, 406b, 406c. FIG. 4B provides the handle apparatus 402 (FIG. 4) showing the grip portions 416a, 416b in an expanded position to create space for the interconnect bridge 102.

Referring back to FIG. 4, in some implementations, when the interconnect bridge 102 is secured in the handle apparatus 402, stoppers are provided to prevent the interconnect bridge 102 from being displaced. For example, the outer fin 404 can include one or more stoppers 412a, 412b. The one or more stoppers 412a, 412b on the outer fin 404 can interface with the third side edge 438 to prevent the interconnect bridge 102 from dislodging in the +x-direction. In another example, the first bracket portion 410 can include a stopper 414b and/or the second bracket portion 408 can include a stopper 414a. The stoppers 414a, 414b can interface with the fourth side edge 440 of the interconnect bridge 102 and prevent the interconnect bridge 102 from dislodging in the -x-direction. In some implementations, stoppers similar to the stoppers 414a, 414b are provided for preventing dislodging in the +x-direction instead of (or in addition to) the one or more stoppers 414a, 412b. Each provided stopper in the handle apparatus 402 can prevent motion of the interconnect bridge 102 in a single lateral direction.

In some implementations, edges on the bracket portions (e.g., edge 428 of the first bracket portion 410 and edge 426 of the second bracket portion) interface with the first side edge 436 and the second side edge 442 of the interconnect bridge 102 to prevent the interconnect bridge 102 from dislodging in the-y-direction and/or the +y-direction. In some implementations, one or both of the edges 428, 426 are ribbed such that only specific segments of the edges 428, 426 interface with the first side edge 436 and the second side edge 442.

In some implementations, the grip attachment 416 prevents the interconnect bridge 102 from being dislodged in the +z-direction. The first grip portion 416a can be positioned in a spacing between planes formed by the outer fin 404 and the first inner fin 406a, and the second grip portion 416b can be positioned in a spacing between planes formed by the second inner fin 406b and the third inner fin 406c. In some implementations, stoppers can be provided on the first bracket portion 410 and the second bracket portion 408 to prevent dislodging in the +z-direction. In some implementations, the one or more inner fins (e.g., the first inner fin 406a, the second inner fin 406b, and the third inner fin 406c) prevent the interconnect bridge 102 from being dislodged in the -z-direction.

In some implementations, the interconnect bridge 102 is: (i) prevented from moving in a first direction (e.g.,-z-direction) by the one or more inner fins 406a, 406b, 406c; (ii) prevented from moving in a second direction (e.g., +x-direction) by the outer fin 404; (iii) prevented from moving in a third direction (e.g., +z-direction) by the grip attachment 416; (iv) prevented from moving in a fourth direction (e.g., −x-direction) and a fifth direction (e.g., +y-direction) by the first bracket portion 410; and (v) prevented from moving in the fourth direction and a sixth direction (e.g., −y-direction) by the second bracket portion 408.

In some implementations, the first bracket portion 410 includes an orientation marker 424. The orientation marker 424 provides an indication of directionality associated with the handle apparatus 402 and/or the interconnect bridge 102 when installed in the handle apparatus 402.

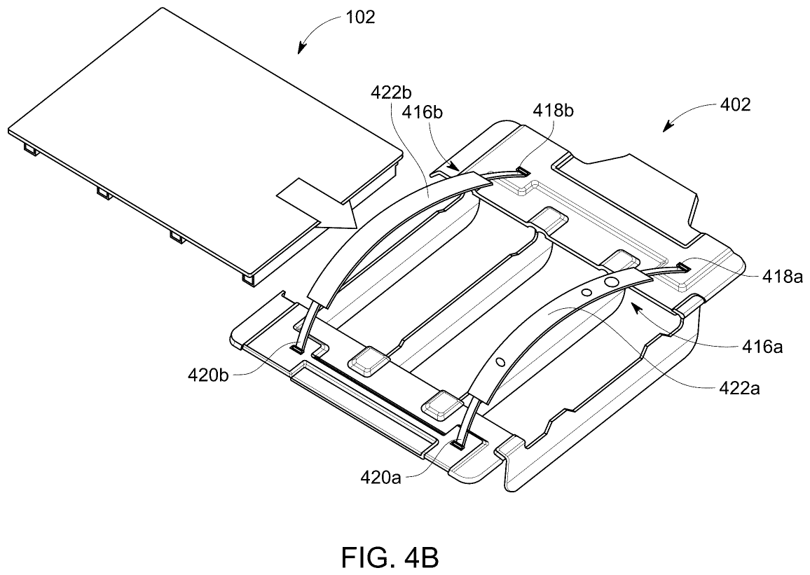

Referring to FIG. 5, a top perspective view showing a bridge-handle combination 500 is provided, according to certain aspects of the present disclosure. The bridge-handle combination 500 includes the interconnect bridge 102 secured in the handle apparatus 402. The bridge-handle combination 500 shows stoppers 412a, 412b interfacing with the third side edge 438 of the interconnect bridge 102 and stoppers 414a, 414b interfacing with the fourth side edge 440. The bridge-handle combination 500 further shows the grip attachment 416 position when the interconnect bridge 102 is secured.

Referring to FIG. 6, a bottom perspective view of the bridge-handle combination 500 is provided, according to certain aspects of the present disclosure. In the bridge-handle combination 500, the interconnect bridge 102 is installed in a correct orientation into the handle apparatus 402. The two or more connectors 432a, 432b, 432c, 432d protrude from a bottom surface 634 of the interconnect bridge 102. In some implementations, a separation 606 between the first connector 432a and the second connector 432b is the same as a separation 602 between the outer fin 404 and the first inner fin 406a. In some implementations, a separation 608 between the second connector 432b and the third connector 432c is the same as a separation 604 between the first inner fin 406a and the second inner fin 406b. In some implementations, the separation between adjacent inner fins (e.g., the second inner fin 406b and the third inner fin 406c) is the same as the separation between the outer fin 404 and the first inner fin 406a.

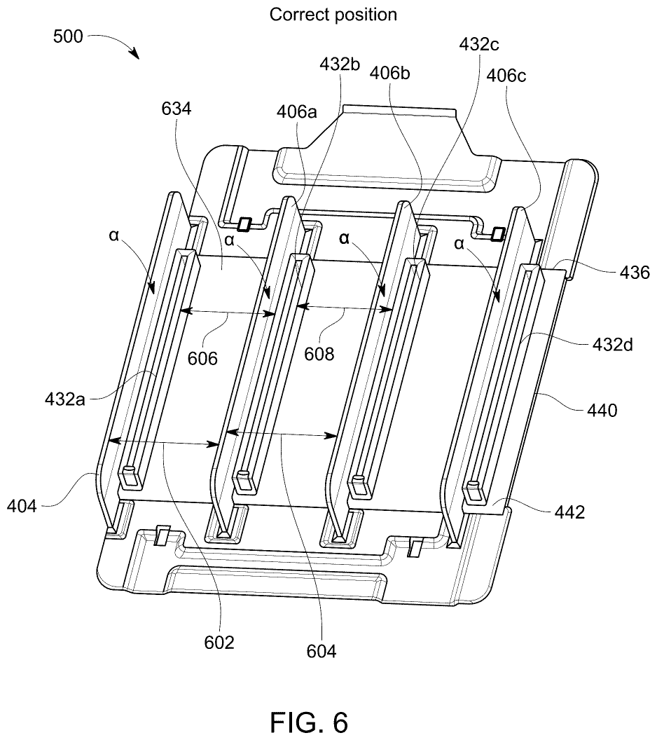

Referring to FIG. 7, a bottom perspective view of an incorrectly installed bridge-handle combination 700 is provided. When the interconnect bridge 102 is incorrectly installed, a spacing between corresponding connectors (e.g., the connectors 432a, 432b, 432c, 432d, etc.) and corresponding fins (e.g., the outer fin 404, the inner fins 406a, 406b, 406c, etc.) widens. For example, comparing FIG. 6 to FIG. 7, the spacing indicated by α is less than the spacing indicated by β. For example, the spacing in FIG. 6 can be about 0.4 mm, and the spacing in FIG. 7 can be about 5.8 mm. In some implementations, because α and β can have an order of magnitude difference, an incorrect installation can be visually spotted without need to try installing the bridge-handle combination 700 in a computing system.

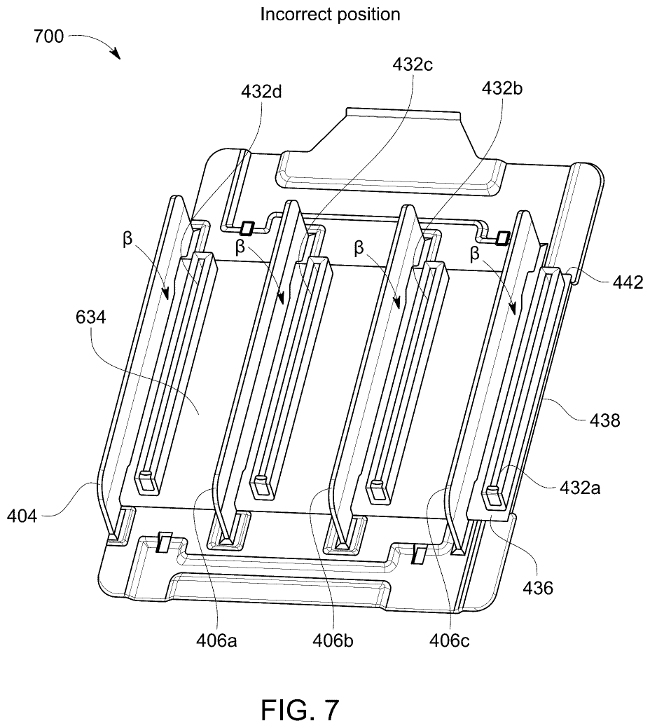

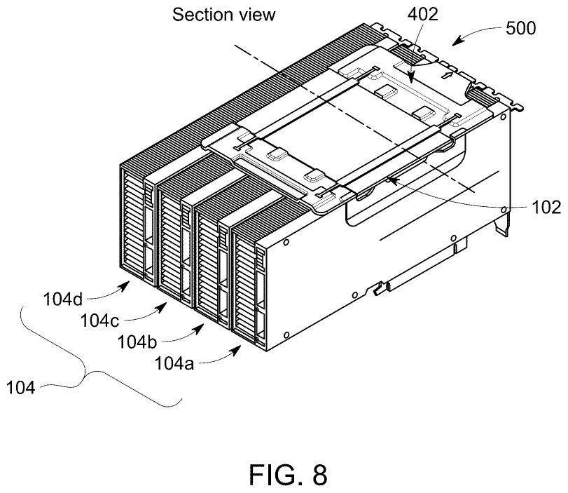

Referring to FIG. 8, a perspective view showing the bridge-handle combination 500 (FIG. 5) interfaced with the set of expansion cards 104, according to certain aspects of the present disclosure. Referring to FIG. 9, a cross-sectional view of the bridge-handle combination 500 and the set of expansion cards 104 is provided, according to certain aspects of the present disclosure. The first computing expansion card 104a includes a printed circuit board 902a having the board connector 106a and a bridge connector 904a. The second computing expansion card 104b includes a printed circuit board 902b having a board connector 106b and a bridge connector 904b. The third computing expansion card 104c includes a printed circuit board 902c having the board connector 106c and a bridge connector 904c. The fourth computing expansion card 104d includes a printed circuit board 902d having a board connector 106d and a bridge connector 904d. The board connectors 106a, 106b, 106c, 106d can connect to PCIe connectors on a motherboard of a computing system. The bridge connectors 904a, 904b, 904c, 904d can provide golden fingers or connections that can be received in the connectors 432a, 432b, 432c, 432d. The connector matings 202a, 202b, 202c, 202d indicate proper sitting and physical connection between the bridge connectors 904a, 904b, 904c, 904d and the connectors 432a, 432b, 432c, 432d.

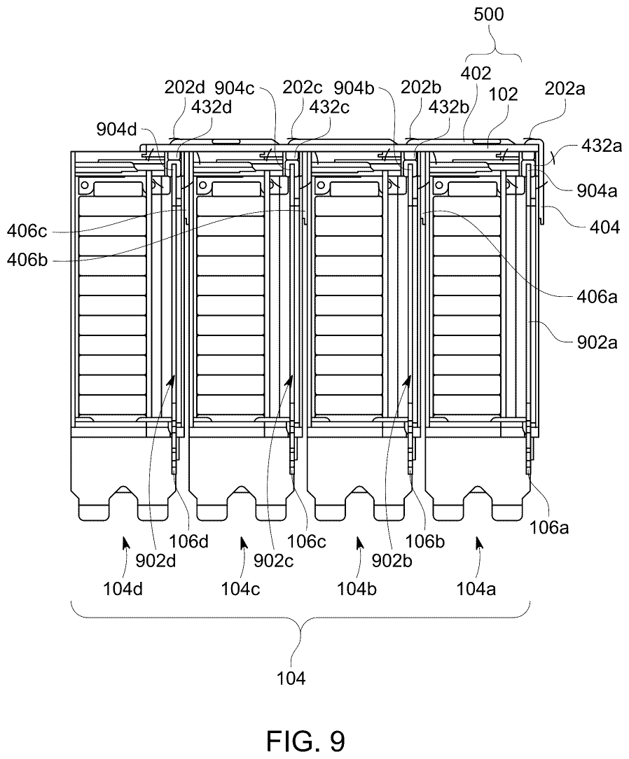

Referring to FIG. 10, a perspective view showing connector matings of the bridge-handle combination 500 and the set of computing expansion cards 104 of FIG. 8 is provided.

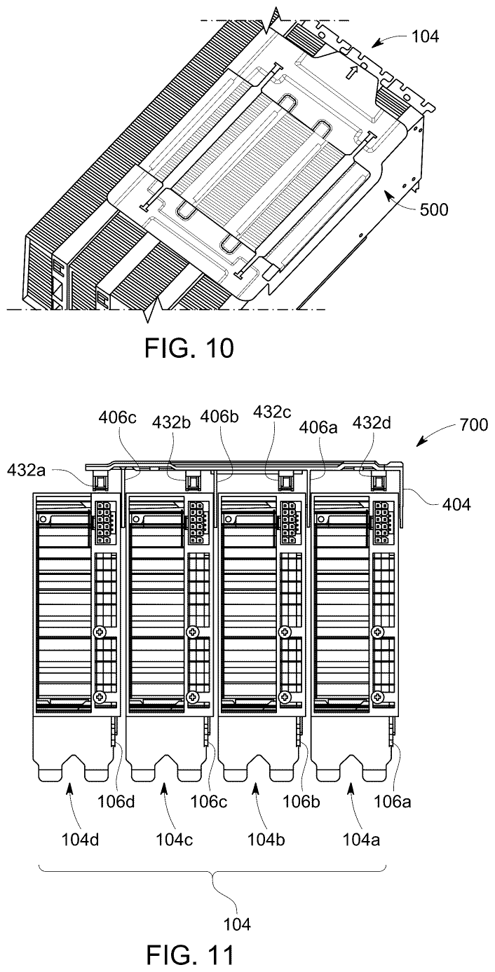

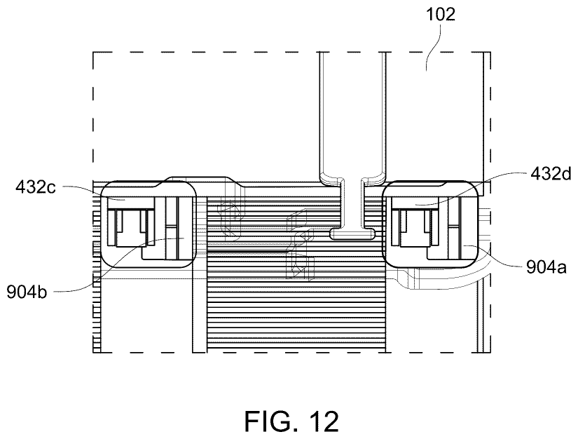

Referring to FIG. 11, a cross-sectional view of the incorrectly installed bridge-handle combination 700 (FIG. 7) aligned with the set of expansion cards 104 is provided, according to certain aspects of the present disclosure. When incorrectly installed, the connectors 432a, 432b, 432c, 432d of the interconnect bridge 102 will come in contact with the surface of the set of expansion cards 104, thereby preventing an attempt to force the interconnect bridge 102 to mate with bridge connectors (e.g., the bridge connectors 904a, 904b, 904c, 904d of FIG. 9) of the set of expansion cards 104. The connectors of the interconnect bridge 102 will not be aligned with any golden finger provided by the connectors. Due to the non-alignment between the connectors and the golden fingers, even if an attempt is made to install the bridge-handle combination 700, the connectors will not come close to the golden fingers for any type of damage to occur. Referring to FIG. 12, a perspective view showing connector positioning of FIG. 11 is provided. As shown, the handle apparatus 402 prevents any attempt of an incorrect positioning of the interconnect bridge 102 from aligning with the golden fingers of the bridge connectors 904a, 904b, thus preventing any attempt of an improper mating that can cause connector damage.

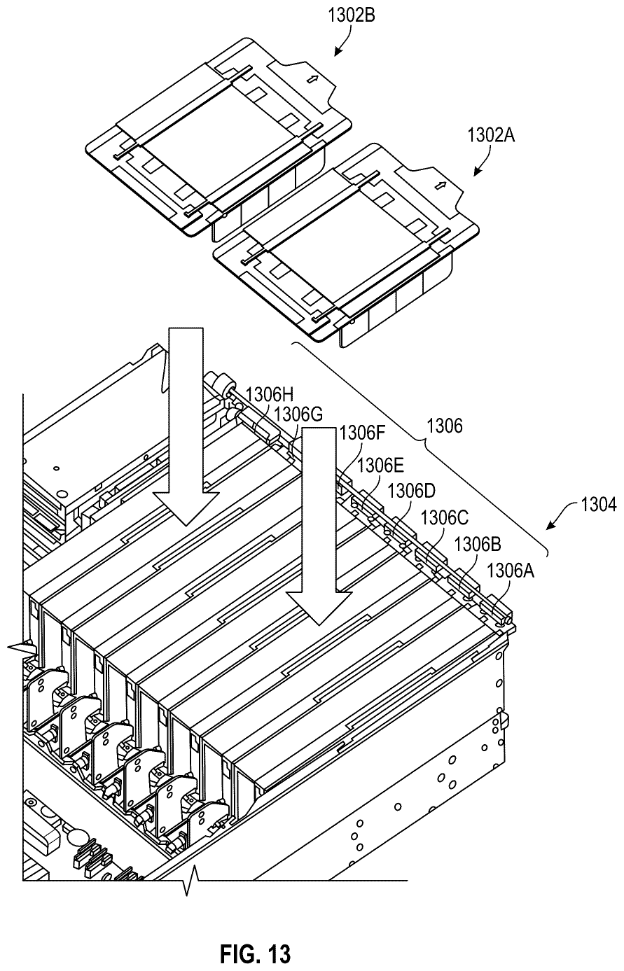

FIG. 13 provides a perspective view showing a first bridge-handle combination 1302A and a second bridge-handle combination 1302B being installed in a computing system 1304, according to certain aspects of the present disclosure. The first and second bridge-handle combinations 1302A, 1302B are similar to or the same as the bridge-handle combination 500. The computing system 1304 includes a plurality of computing expansion cards 1306 (e.g., GPUs). The plurality of computing expansion cards 1306 includes a first set of computing expansion cards 1306A, 1306B, 1306C, 1306D and a second set of computing expansion cards 1306e, 1306f, 1306g, 1306h. At least one expansion card in the plurality of computing expansion cards 1306 is mechanically and electrically coupled to a circuit board (e.g., a motherboard) of the computing system 1304.

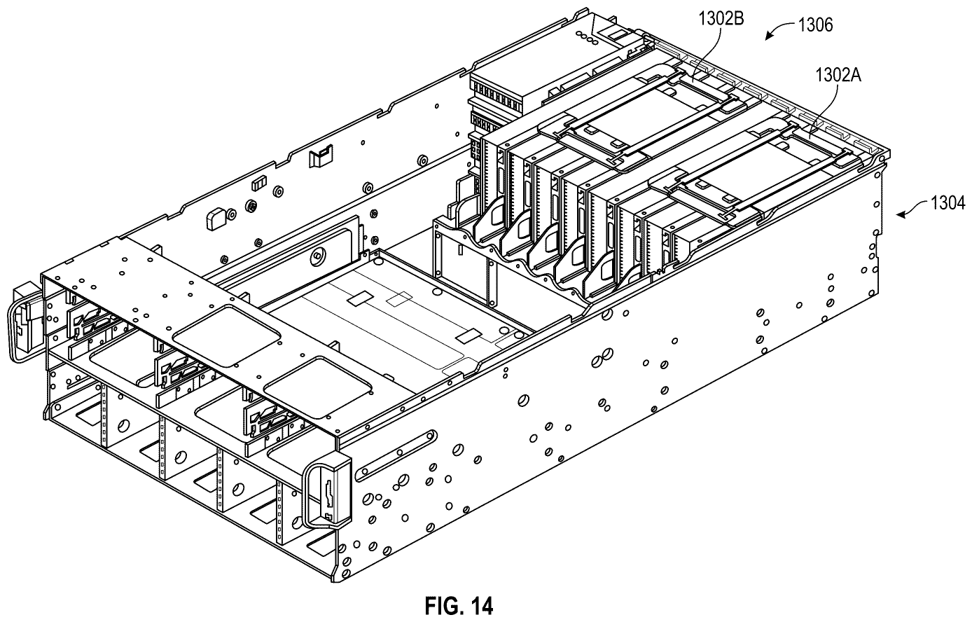

Referring to FIG. 14, a perspective view of the computing system 1304 after installing the bridge-handle combinations 1302A, 1302B is provided, according to certain aspects of the present disclosure. The first bridge-handle combination 1302A is coupled to the first set of computing expansion cards 1306A, 1306B, 1306C, 1306D. The second bridge-handle combination 1302B is coupled to the second set of computing expansion cards 1306e, 1306f, 1306g, 1306h.

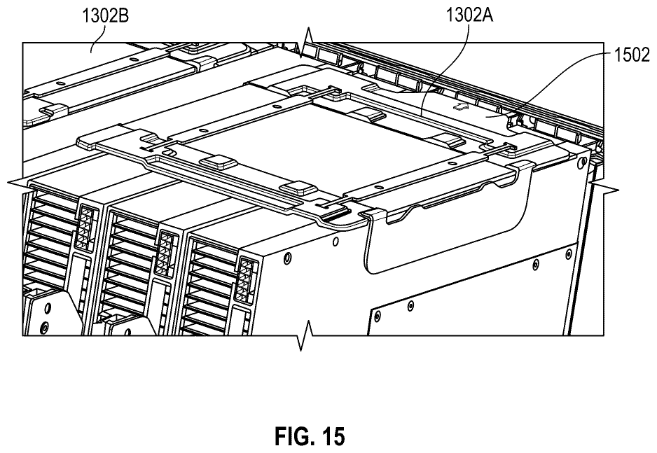

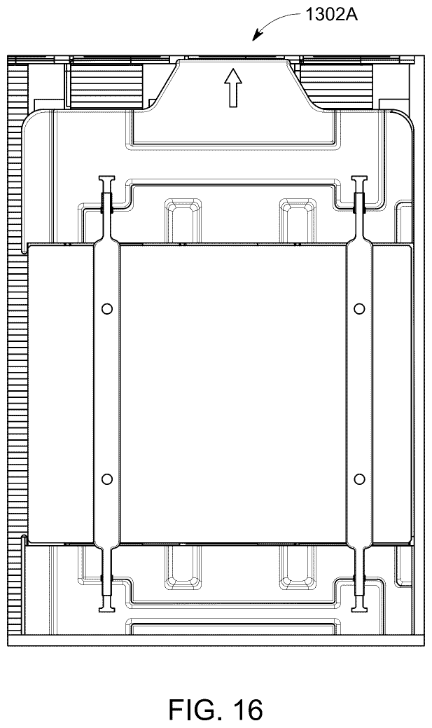

Referring to FIG. 15, a perspective view of the installed first and second bridge-handle combinations 1302A, 1302B is provided. An orientation marker 1502 of the first bridge-handle combination 1302A points toward PCI bracket of the first set of computing expansion cards 1306A, 1306B, 1306C, 1306D. Referring to FIG. 16, a top plan view of the first bridge-handle combination 1302A showing stopper positions that prevent lateral movement of the interconnect bridge of the first bridge-handle combination 1302A.

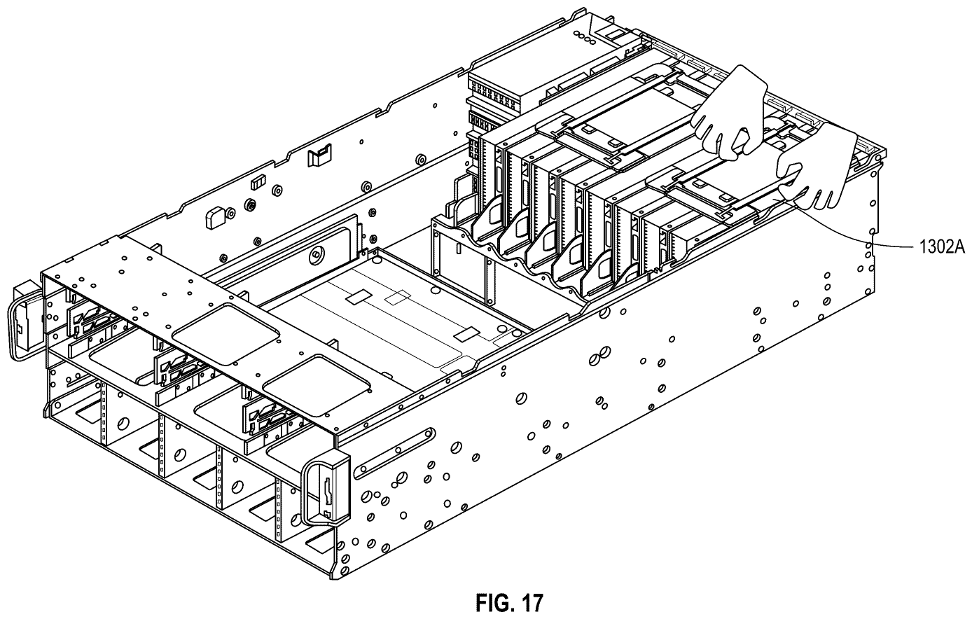

FIG. 17 shows a perspective view showing removal of the first bridge-handle combination 1302A. To remove the first bridge-handle combination 1302A from the computing system 1304, grip portions of the first bridge-handle combination 1302A are lifted at the same time. Lifting the grip portions at the same time can prevent unequal dislodging of connectors of the interconnect bridge of the first bridge-handle combination 1302A.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A handle apparatus for receiving an interconnect bridge of a computing system, the handle apparatus comprising:
a grip attachment; and
a bracket coupled to the grip attachment and including:
a first bracket portion having a first top surface and a first bottom surface, the first top surface being located opposite the first bottom surface,
a second bracket portion having a second top surface and a second bottom surface, the second top surface being located opposite the second bottom surface, the first top surface being coupled with the second top surface via the grip attachment,
an inner fin, and
an outer fin separated from the inner fin by a fin spacing, the outer fin being parallel to the inner fin, the outer fin and the inner fin coupling the first and second bottom surfaces.

2. The handle apparatus of claim 1, wherein the grip attachment includes a first grip portion and a second grip portion, each of the first grip portion and the second grip portion independently coupling the first bracket portion to the second bracket portion on the first and second top surfaces.

3. The handle apparatus of claim 2, wherein the inner fin includes a first inner fin, a second inner fin, and a third inner fin, and wherein the first grip portion is positioned in a spacing between the outer fin and the first inner fin and the second grip portion is positioned in a spacing between the second inner fin and the third inner fin.

4. The handle apparatus of claim 3, wherein the grip attachment includes a first grip having a grip body made with elastic material.

5. The handle apparatus of claim 1, wherein the outer fin includes one or more stoppers, the one or more stoppers configured to prevent motion of the interconnect bridge in a single lateral direction.

6. The handle apparatus of claim 1, wherein the first bracket portion includes a first stopper or the second bracket portion includes a second stopper, the first stopper and/or the second stopper configured to prevent motion of the interconnect bridge in a single lateral direction.

7. The handle apparatus of claim 1, wherein the interconnect bridge is (i) prevented from moving in a first direction by the inner fin, (ii) prevented from moving in a second direction by the outer fin, (iii) prevented from moving in a third direction by the grip attachment, (iv) prevented from moving in a fourth direction and a fifth direction by the first bracket portion, and (v) prevented from moving in the fourth direction and a sixth direction by the second bracket portion, wherein the first direction, the second direction, the third direction, the fourth direction, the fifth direction, and the sixth direction are all different directions.

8. The handle apparatus of claim 1, wherein the interconnect bridge is an NVLink bridge.

9. A computing system comprising:
a circuit board;
a plurality of computing expansion cards electrically coupled to the circuit board, the plurality of computing expansion cards including a first set of computing expansion cards; and
a first bridge-handle combination coupled to the first set of computing expansion cards, wherein a bridge-handle combination includes a handle apparatus securing an interconnect bridge, the handle apparatus including:
a grip attachment; and
a bracket coupled to the grip attachment and including:
a first bracket portion having a first top surface and a first bottom surface, the first top surface being located opposite the first bottom surface,
a second bracket portion having a second top surface and a second bottom surface, the second top surface being located opposite the second bottom surface, the first top surface being coupled with the second top surface via the grip attachment,
an inner fin, and
an outer fin separated from the inner fin by a fin spacing, the outer fin being parallel to the inner fin, the outer fin and the inner fin coupling the first and second bottom surfaces.

10. The computing system of claim 9, wherein the circuit board is a motherboard and the plurality of computing expansion cards is a plurality of graphical processing units.

11. The computing system of claim 10, wherein the interconnect bridge of the first bridge-handle combination is an NVLink bridge.

12. The computing system of claim 9, further comprising:
a second bridge-handle combination, and
wherein the plurality of computing expansion cards further includes a second set of computing expansion cards, and wherein the second set of computing expansion cards is coupled to the second bridge-handle combination.

13. The computing system of claim 9, wherein the grip attachment includes a first grip portion and a second grip portion, each of the first grip portion and the second grip portion independently coupling the first bracket portion to the second bracket portion on the first and second top surfaces.

14. The computing system of claim 13, wherein the inner fin includes a first inner fin, a second inner fin, and a third inner fin, and wherein the first grip portion is positioned in a spacing between the outer fin and the first inner fin and the second grip portion is positioned in a spacing between the second inner fin and the third inner fin.

15. The computing system of claim 14, wherein the grip attachment includes a first grip having a grip body made with elastic material.

16. The computing system of claim 9, wherein the outer fin includes one or more stoppers, the one or more stoppers configured to prevent motion of the interconnect bridge in a single lateral direction.

17. The computing system of claim 9, wherein the first bracket portion includes a first stopper or the second bracket portion includes a second stopper, the first stopper and/or the second stopper configured to prevent motion of the interconnect bridge in a single lateral direction.

18. The computing system of claim 9, wherein a separation between connectors of the interconnect bridge is the fin spacing.

19. The computing system of claim 9, wherein the first bracket portion includes an orientation marker.

20. The computing system of claim 19, wherein the orientation marker points toward a PCI bracket of the computing expansion cards.
